(19) United States
(12) Patent Application Publication
(10) Pub. No.: US 2024/0258472 A1
(43) Pub. Date: Aug. 1, 2024

(54) DISPLAY DEVICE AND MANUFACTURING METHOD THEREOF

(71) Applicant: Samsung Display Co., LTD., Yongin-si (KR)

(72) Inventor: Bo Geon JEON, Yongin-si (KR)

(21) Appl. No.: 18/478,745

(22) Filed: Sep. 29, 2023

(30) Foreign Application Priority Data
Jan. 27, 2023 (KR) 10-2023-0011183

(51) Int. Cl. H01L 33/52; H01L 25/16

(52) U.S. Cl. CPC H01L 33/52; H01L 25/167; H01L 2933/005

(57) ABSTRACT

A display device and a manufacturing method of a display device are provided. A manufacturing method of a display device includes transferring light emitting elements onto a first electrode arranged on a pixel circuit layer, each of the light emitting elements including an undoped semiconductor layer spaced apart from the pixel circuit layer, patterning an inorganic layer covering the light emitting elements on the first electrode, forming a photosensitive material layer on the inorganic layer, and patterning the photosensitive material layer to expose a portion of the inorganic layer covering the undoped semiconductor layer.

### CROSS-REFERENCE TO RELATED APPLICATION

This application claims priority to and the benefit of Korean Patent Application No. 10-2023-0011183, filed Jan. 27, 2023 in the Korean Intellectual Property Office, the entire content of which is hereby incorporated by reference.

### BACKGROUND

### 1. Field

Aspects of embodiments of the present invention relate to a display device and a manufacturing method of a display device.

### 2. Description of the Related Art

As information technology develops, the importance of a display device, which is a connection medium between a user and information, has been emphasized. The display device may display an image using a light emitting element generating light by recombination of electrons emitted from a cathode electrode and holes emitted from an anode electrode.

### SUMMARY

According to an aspect of embodiments of the present invention, a display device capable of improving contact resistance between an N-type semiconductor layer and a cathode electrode of a light emitting element is provided.

According to one or more embodiments of the present invention, a manufacturing method of a display device includes: transferring light emitting elements onto a first electrode arranged on a pixel circuit layer, each of the light emitting elements including an undoped semiconductor layer spaced apart from the pixel circuit layer; patterning an inorganic layer covering the light emitting elements on the first electrode; forming a photosensitive material layer on the inorganic layer; and patterning the photosensitive material layer to expose a portion of the inorganic layer covering the undoped semiconductor layer.

The inorganic layer may include at least one of silicon oxide and silicon nitride.

The patterning the photosensitive material layer may include exposing and developing the photosensitive material layer using a halftone mask.

The manufacturing method of the display device may further include etching an exposed portion of the inorganic layer using a first etching gas.

The first etching gas may include at least tetrafluoromethane.

The manufacturing method of the display device may further include etching at least a portion of the undoped semiconductor layer using a second etching gas.

The second etching gas may include at least boron trichloride.

In the etching the at least the portion of the undoped semiconductor layer, at least a portion of the patterned photosensitive material layer may be etched.

The manufacturing method of the display device may further include removing the patterned photosensitive material layer remaining unetched.

The manufacturing method of the display device may further include forming an organic layer in contact with the inorganic layer between the light emitting elements.

The manufacturing method of the display device may further include forming a second electrode on the light emitting elements, the inorganic layer, and the organic layer.

According to one or more embodiments of the present invention, a display device includes: a pixel circuit layer including a base layer and a pixel circuit; a first electrode disposed on the pixel circuit layer; light emitting elements disposed on the first electrode and each including a first semiconductor layer including a first type semiconductor; an inorganic layer disposed on the first electrode and covering the light emitting elements; and a second electrode disposed on the light emitting elements. The first semiconductor layer and the inorganic layer may contact the second electrode.

Each of the light emitting elements may further include a second semiconductor layer including a second type semiconductor different from the first type semiconductor; an active layer disposed between the first semiconductor layer and the second semiconductor layer; and an electrode layer disposed on the second semiconductor layer. The second semiconductor layer, the active layer, and the electrode layer may be disposed between the first electrode and the first semiconductor layer.

Each of the light emitting elements may further include an insulating layer surrounding at least a portion of each of the first semiconductor layer, the second semiconductor layer, the active layer, and the electrode layer

The inorganic layer may include at least one of silicon oxide and silicon nitride.

The display device may further include an organic layer between the light emitting elements and contacting the inorganic layer and the second electrode.

### BRIEF DESCRIPTION OF THE DRAWINGS

The above and other features of the disclosure will become more apparent by describing in further detail some embodiments thereof with reference to the accompanying drawings, in which:

FIG. 1 is a plan view illustrating a display device in accordance with an embodiment.

FIG. 2 is a diagram illustrating an example of a pixel of FIG. 1.

FIG. 3 is a cross-sectional view illustrating a display device in accordance with an embodiment.

FIG. 4 is a block diagram for explaining a manufacturing method of a display device in accordance with an embodiment.

FIGS. 5 to 14 are diagrams schematically illustrating the manufacturing method of the display device according to FIG. 4.

### DETAILED DESCRIPTION

The present invention now will be described more fully herein with reference to the accompanying drawings, in which various embodiments are shown. The present invention may, however, be embodied in many different forms, and should not be construed as limited to the embodiments set forth herein. Rather, these embodiments are provided so that this disclosure will be thorough and complete, and will fully convey the scope of the invention to those skilled in the art.

In describing the drawings, like reference numerals have been used for like elements. In the accompanying drawings, the dimensions of structures or components may be enlarged in order to clearly explain the invention. It is to be understood that, although the terms “first,” “second,” etc. may be used herein to describe various elements, these elements should not be limited by these terms. These terms are used to distinguish one element from another element. For instance, a first element discussed below could be termed a second element without departing from the scope of the invention. Similarly, the second element could also be termed the first element.

The terminology used herein is for the purpose of describing particular embodiments and is not intended to be limiting. As used herein, “a,” “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It is to be further understood that the terms “comprises” and/or “comprising,” or “includes” and/or “including,” when used in this specification, specify the presence of stated features, regions, integers, steps, operations, elements, and/or components, but do not preclude the presence or addition of one or more other features, regions, integers, steps, operations, elements, components, and/or groups thereof.

Further, relative terms, such as “lower” or “bottom” and “upper” or “top,” may be used herein to describe one element's relationship to another element as illustrated in the figures. It is to be understood that relative terms are intended to encompass different orientations of the device in addition to the orientation depicted in the figures. For example, if the device in one of the figures is turned over, elements described as being on the “lower” side of other elements would then be oriented on “upper” sides of the other elements. The term “lower” can, therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It is to be further understood that terms, such as those defined in commonly used dictionaries, should be interpreted as having a meaning that is consistent with their meaning in the context of the relevant art and the present disclosure, and are not to be interpreted in an idealized or overly formal sense unless expressly so defined herein.

Herein, some embodiments of the present invention will be described in further detail with reference to the accompanying drawings.

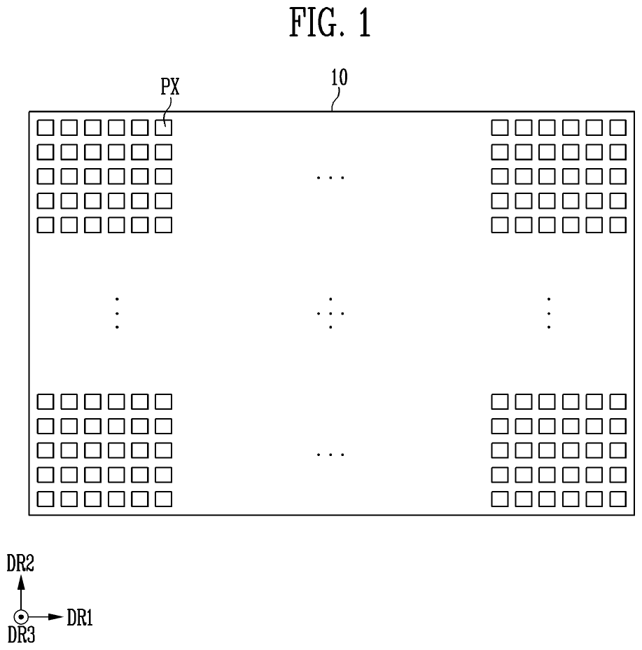

FIG. 1 is a plan view illustrating a display device according to an embodiment.

Referring to FIG. 1, a display device 10 may be configured to output optical information. For example, the display device 10 may be a device for displaying a moving or still image, which can be applied to various devices. In an embodiment, the display device 10 may be formed in the shape of a rectangular flat plate having a long side in a first direction DR1 and a short side in a second direction DR2 intersecting the first direction DR1. A corner portion where the long side in the first direction DR1 and the short side in the second direction DR2 meet may be rounded to have a curvature (e.g., a predetermined curvature) or may be formed at a right angle. However, a planar shape of the display device 10 is not limited to a rectangle, but may be a polygonal shape, a circular shape, an elliptical shape, or the like. The display device 10 may be formed flat, but embodiments of the present invention are not limited thereto. For example, the display device 10 may include a curved portion formed at left and right ends and having a constant or changing curvature. In addition, the display device 10 may be flexible so as to be bendable, foldable, or rollable.

The display device 10 may further include pixels PX for displaying an image, scan lines extending in the first direction DR1, and data lines extending in the second direction DR2. The pixels PX may be arranged in a matrix form in the first direction DR1 and the second direction DR2.

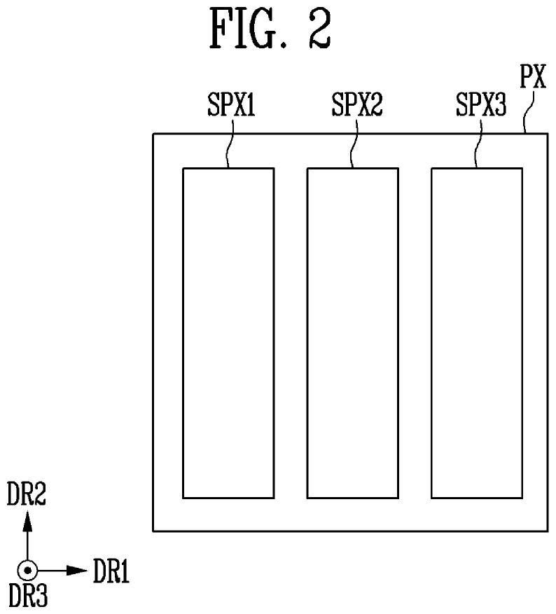

FIG. 2 is a diagram illustrating an example of a pixel of FIG. 1.

Referring to FIG. 2, each of the pixels PX may include a plurality of sub-pixels SPX1, SPX2, and SPX3. FIG. 2 shows an embodiment in which each of the pixels PX includes three sub-pixels SPX1, SPX2, and SPX3, that is, a first sub-pixel SPX1, a second sub-pixel SPX2, and a third sub-pixel SPX3, but embodiments of the present invention are not limited thereto.

The first sub-pixel SPX1, the second sub-pixel SPX2, and the third sub-pixel SPX3 may be connected to any one of the data lines and at least one of the scan lines.

In an embodiment, each of the first sub-pixel SPX1, the second sub-pixel SPX2, and the third sub-pixel SPX3 may have a rectangular, square, or rhombic planar shape. For example, each of the first sub-pixel SPX1, the second sub-pixel SPX2, and the third sub-pixel SPX3 may have a rectangular planar shape having a short side in the first direction DR1 and a long side in the second direction DR2. According to an embodiment, each of the first sub-pixel SPX1, the second sub-pixel SPX2, and the third sub-pixel SPX3 may have a square or rhombic planar shape including sides having equal lengths in the first direction DR1 and the second direction DR2.

The first sub-pixel SPX1, the second sub-pixel SPX2, and the third sub-pixel SPX3 may be arranged in the first direction DR1. In another embodiment, any one of the second sub-pixel SPX2 and the third sub-pixel SPX3 and the first sub-pixel SPX1 may be arranged in the first direction DR1, and the other one and the first sub-pixel SPX1 may be arranged in the second direction DR2. In another embodiment, any one of the first sub-pixel SPX1 and the third sub-pixel SPX3 and the second sub-pixel SPX2 may be arranged in the first direction DR1, and the other one and the second sub-pixel SPX2 may be arranged in the second direction DR2. In another embodiment, any one of the first sub-pixel SPX1 and the second sub-pixel SPX2 and the third sub-pixel SPX3 may be arranged in the first direction DR1, and the other one and the third sub-pixel SPX3 may be arranged in the second direction DR2.

The first sub-pixel SPX1 may emit first light, the second sub-pixel SPX2 may emit second light, and the third sub-pixel SPX3 may emit third light. In an embodiment, the first light may be light in a red wavelength band, the second light may be light in a green wavelength band, and the third light may be light in a blue wavelength band. In an embodiment, the red wavelength band may be a wavelength range of approximately 600 nm to 750 nm, the green wavelength band may be a wavelength range of approximately 480 nm to 560 nm, and the blue wavelength band may be a wavelength range of approximately 370 nm to 460 nm, but embodiments of the present invention are not limited to the above examples.

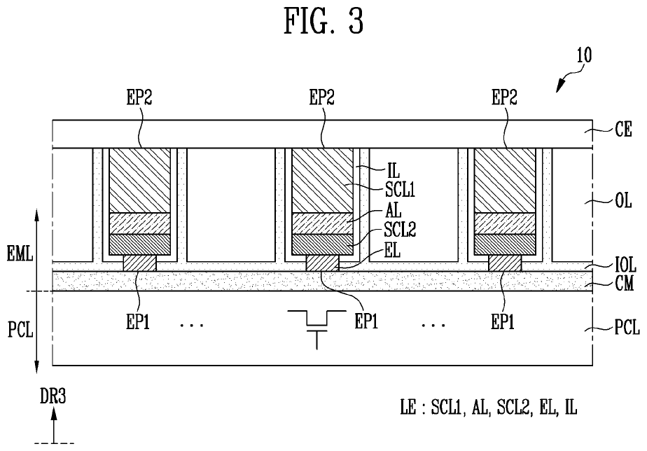

Each of the first sub-pixel SPX1, the second sub-pixel SPX2, and the third sub-pixel SPX3 may include an inorganic light emitting element having an inorganic semiconductor as a light emitting element LE (refer to FIG. 3) that emits light.

An area of the first sub-pixel SPX1, an area of the second sub-pixel SPX2, and an area of the third sub-pixel SPX3 may be substantially equal to each other, but embodiments of the present invention are not limited thereto. At least one of the area of the first sub-pixel SPX1, the area of the second sub-pixel SPX2, and the area of the third sub-pixel SPX3 may be different from at least one of the others. In an embodiment, two of the area of the first sub-pixel SPX1, the area of the second sub-pixel SPX2, and the area of the third sub-pixel SPX3 may be substantially equal to each other, and the other one may be different from the two. In another embodiment, the area of the first sub-pixel SPX1, the area of the second sub-pixel SPX2, and the area of the third sub-pixel SPX3 may be different from each other.

FIG. 3 is a cross-sectional view illustrating the display device according to an embodiment.

Referring to FIG. 3, the display device 10 may include a pixel circuit layer PCL and a light emitting element layer EML.

The pixel circuit layer PCL may be a layer including a pixel circuit for driving light emitting elements LE. The pixel circuit layer PCL may include a substrate (or base layer), metal layers for forming the pixel circuit, and insulating layers disposed between the metal layers.

The substrate may be a base substrate or a base member for supporting the display device 10. In an embodiment, the substrate may be a rigid substrate made of glass. In another embodiment, the substrate may be a flexible substrate that can be bent, folded, or rolled. In an embodiment, the substrate may include an insulating material, such as a polymer resin including polyimide.

The pixel circuit may include a thin film transistor. The pixel circuit may further include a storage capacitor. The pixel circuit may be electrically connected to the light emitting elements LE to provide an electrical signal such that the light emitting elements LE emit light.

The light emitting element layer EML may be disposed on the pixel circuit layer PCL. In an embodiment, the light emitting element layer EML may include a first electrode CM, a second electrode CE, the light emitting elements LE, an inorganic layer IOL, and an organic layer OL.

The first electrode CM may be disposed on the pixel circuit layer PCL. The first electrode CM may be disposed below the light emitting elements LE and electrically connected to the light emitting elements LE. For example, the first electrode CM may be electrically connected to the light emitting elements LE through a first end EP1 adjacent to an electrode layer EL of each of the light emitting elements LE.

The first electrode CM may be electrically connected to a pixel circuit (for example, a driving transistor, etc.) formed in the pixel circuit layer PCL. In an embodiment, the first electrode CM may be an anode electrode and may receive an anode signal for driving the light emitting elements LE.

The second electrode CE may be disposed above the light emitting elements LE and electrically connected to the light emitting elements LE. For example, the second electrode CE may be electrically connected to the light emitting elements LE through a second end EP2 adjacent to a first semiconductor layer SCL1 of each of the light emitting elements LE.

In an embodiment, the second electrode CE may be a cathode electrode and may receive a cathode signal. The second electrode CE may supply a voltage of a power source line to the light emitting elements LE.

The first electrode CM may be a pixel electrode for the light emitting elements LE, and the second electrode CE may be a common electrode for the light emitting elements LE. The first electrode CM and the second electrode CE may be disposed to face each other with the light emitting elements LE interposed therebetween.

The first electrode CM may include a conductive material. For example, the first electrode CM may include one or more selected from the group consisting of silver (Ag), magnesium (Mg), aluminum (Al), platinum (Pt), palladium (Pd), gold (Au), nickel (Ni), neodymium (Nd), iridium (Ir), chromium (Cr), and titanium (Ti). However, embodiments of the present invention are not limited to the above examples.

The second electrode CE may include a transmissive material. For example, the second electrode CE may include one or more selected from the group consisting of a conductive oxide, such as indium tin oxide (ITO), indium zinc oxide (IZO), zinc oxide (ZnO), indium gallium zinc oxide (IGZO), and indium tin zinc oxide (ITZO), and a conductive polymer, such as poly(3,4-ethylenedioxythiophene) (PEDOT). However, embodiments of the present invention are not limited to the above examples, and the second electrode CE may include a conductive material.

The light emitting elements LE may be disposed on the first electrode CM and electrically connected to the first electrode CM. The light emitting elements LE may be provided to each of the first to third sub-pixels SPX1, SPX2, and SPX3.

The light emitting element LE may be configured to emit light. The light emitting element LE may have any of various shapes. For example, the light emitting element LE may have a pillar shape extending in a direction. However, embodiments of the present invention are not limited to the above examples.

The light emitting element LE may have any of various sizes. For example, the light emitting element LE may have a micro-scale to nano-scale size. However, the size of the light emitting element LE is not limited to a specific numerical range.

The light emitting element LE may include a first semiconductor layer SCL1, a second semiconductor layer SCL2, an active layer AL disposed between the first semiconductor layer SCL1 and the second semiconductor layer SCL2, and the electrode layer EL. According to an embodiment, the light emitting element LE may further include an insulating layer IL.

The light emitting element LE may have the first end EP1 and the second end EP2. The second semiconductor layer SCL2 may be adjacent to the first end EP1 of the light emitting element LE, and the first semiconductor layer SCL1 may be adjacent to the second end EP2. According to an embodiment, a connection layer, that is, the electrode layer EL may be adjacent to the first end EP1.

The first semiconductor layer SCL1 may include a first type semiconductor. The first semiconductor layer SCL1 may include a different type of semiconductor than the second semiconductor layer SCL2. For example, the first semiconductor layer SCL1 may include an N-type semiconductor. For example, the first semiconductor layer SCL1 may include an N-type semiconductor including one or more selected from the group consisting of InAlGaN, GaN, AlGaN, InGaN, AlN, and InN, and doped with a first conductivity type dopant, such as any of Si, Ge, and Sn. However, embodiments of the present invention are not limited to the above examples.

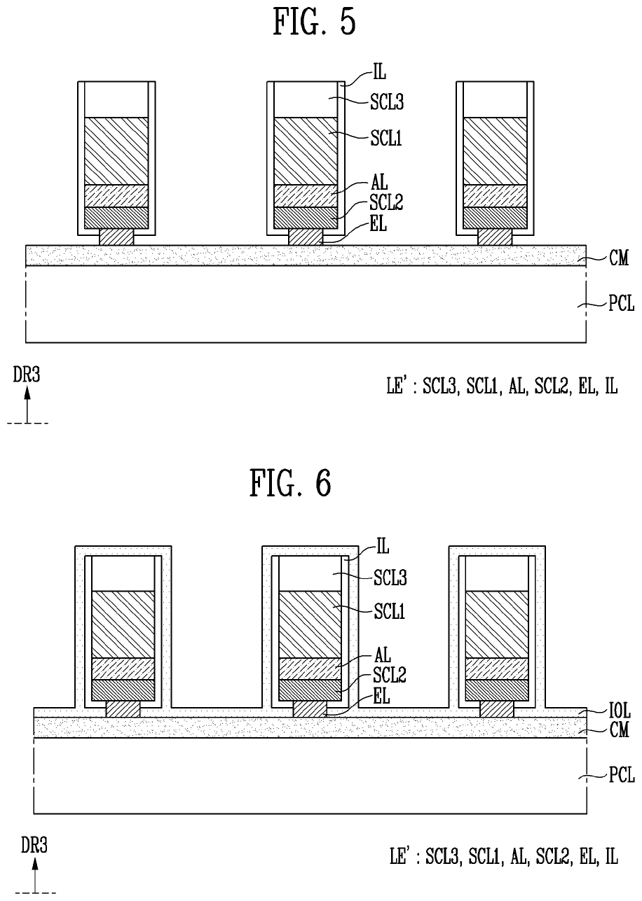

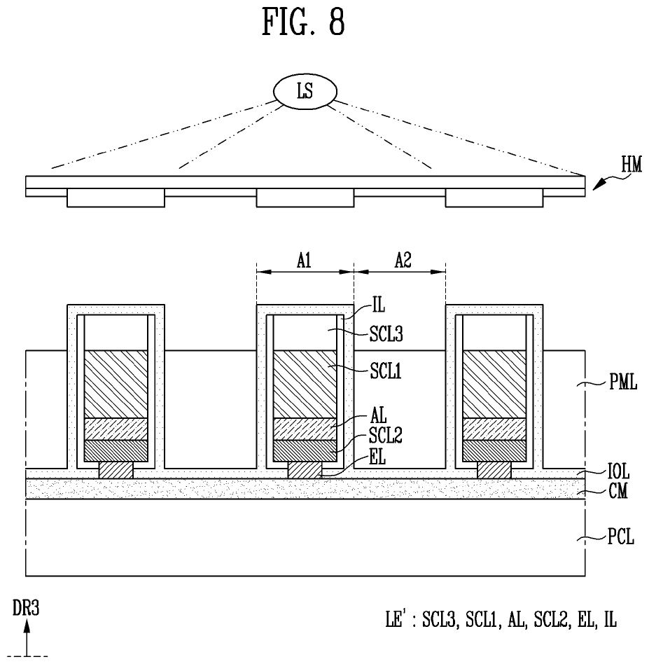

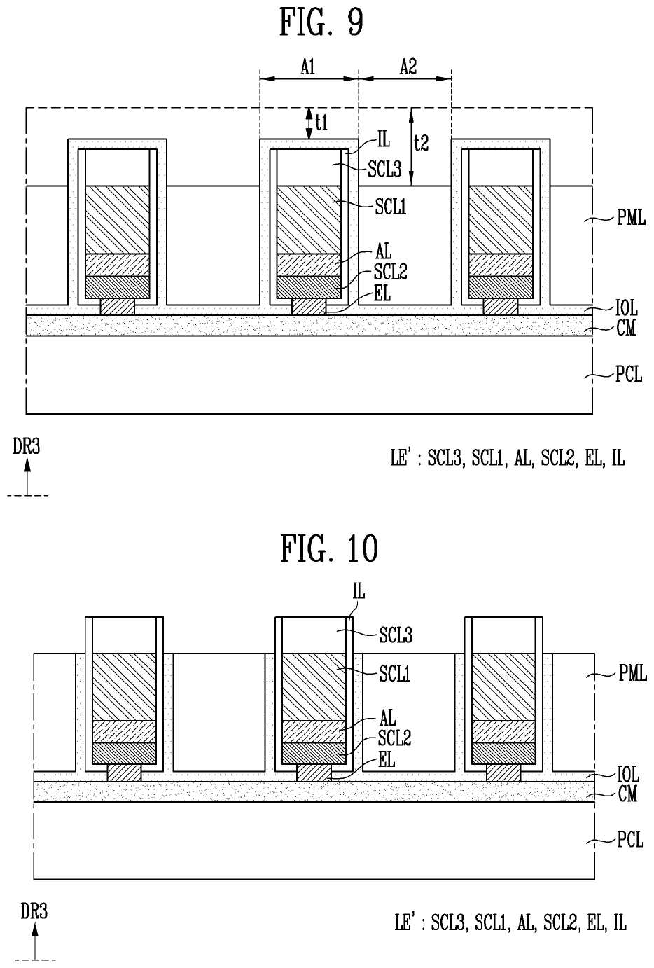

The first semiconductor layer SCL1 may be disposed on the active layer AL and may contact the second electrode CE. That is, a third semiconductor layer SCL3 (refer to FIGS. 5 to 10) may not be disposed between the first semiconductor layer SCL1 and the second electrode CE. Accordingly, contact resistance between the first semiconductor layer SCL1 and the second electrode CE can be improved (or reduced) such that electrons can be smoothly injected into the active layer AL, and light emitting efficiency of the display device 10 can be improved.

The active layer AL may be disposed between the first semiconductor layer SCL1 and the second semiconductor layer SCL2. The active layer AL may include a single-quantum well or multi-quantum well structure. The position of the active layer AL is not limited to a specific example and may be variously changed according to the type of the light emitting element LE.

A clad layer doped with a conductive dopant may be formed on one side and/or the other side of the active layer AL. For example, the clad layer may include one or more of AlGaN and InAlGaN. However, embodiments of the present invention are not limited to the above examples.

When a voltage equal to or higher than a threshold voltage is applied to the first end EP1 and the second end EP2 of the light emitting element LE electrically connected to the first electrode CM and the second electrode CE, electron-hole pairs may be combined with each other in the active layer AL, and the light emitting element LE may emit light. By controlling light emitting of the light emitting element LE using this principle, the light emitting element LE may be used as a light source in various devices.

The second semiconductor layer SCL2 may include a second type semiconductor. The second semiconductor layer SCL2 may be disposed on the active layer AL and may include a different type of semiconductor than the first semiconductor layer SCL1. For example, the second semiconductor layer SCL2 may include a P-type semiconductor. For example, the second semiconductor layer SCL2 may include a P-type semiconductor including one or more selected from the group consisting of InAlGaN, GaN, AlGaN, InGaN, AlN, and InN, and doped with a second conductivity type dopant, such as Ga, B, and Mg. However, embodiments of the present invention are not limited to the above examples.

The electrode layer EL may be disposed on the second semiconductor layer SCL2. The electrode layer EL may be electrically connected to the first electrode CM to apply an emission signal to the light emitting element LE. According to an embodiment, the electrode layer EL may include one or more selected from the group consisting of chromium (Cr), titanium (Ti), aluminum (Al), gold (Au), nickel (Ni), an oxide thereof, and an alloy thereof. In another embodiment, the electrode layer EL may include an alloy (SAC) of tin (Sn), silver (Ag), and copper (Cu) or an alloy of gold (Au) and tin (Sn). However, embodiments of the present invention are not limited to the above examples.

The insulating layer IL may be disposed on a surface of the active layer AL to surround the active layer AL. According to an embodiment, the insulating layer IL may be disposed on a surface of the first semiconductor layer SCL1 to surround the first semiconductor layer SCL1. In addition, the insulating layer IL may be disposed on a surface of the second semiconductor layer SCL2 to surround the second semiconductor layer SCL2. In addition, the insulating layer IL may be disposed on a surface of the electrode layer EL to surround at least a portion of the electrode layer EL.

The insulating layer IL may prevent or substantially prevent an electrical short circuit that may occur when the active layer AL is in contact with a conductive material other than the first semiconductor layer SCL1 and the second semiconductor layer SCL2. In addition, the insulating layer IL may minimize or reduce surface defects of the light emitting element LE to improve life span of the light emitting element LE.

The inorganic layer IOL may be disposed on surfaces of the light emitting elements LE to cover the light emitting elements LE. In addition, the inorganic layer IOL may be disposed on the first electrode CM positioned between the light emitting elements LE. That is, the inorganic layer IOL may be disposed on the first electrode CM as a pattern covering the light emitting elements LE. The inorganic layer IOL may increase the stability of an arrangement of the light emitting elements LE, thereby preventing or substantially preventing the light emitting elements LE from being lifted during a manufacturing process of the display device.

In an embodiment, the inorganic layer IOL may include at least one of silicon oxide (SiOx) and silicon nitride (SiNx). However, embodiments of the present invention are not limited to the above examples. For example, the inorganic layer IOL may further include at least one of aluminum oxide (Al₂O₃), titanium oxide (TiO₂), tantalum oxide (Ta₂O₅), hafnium oxide (HfO₂), and zinc oxide (ZnO₂).

The organic layer OL may be disposed between the light emitting elements LE and may contact the inorganic layer IOL. Further, the organic layer OL may contact the second electrode CE. The organic layer OL, together with the inorganic layer IOL, may increase the stability of the arrangement of the light emitting elements LE, and may protect the light emitting elements LE from foreign substances, such as dust particles. Also, the organic layer OL may planarize upper surfaces of the light emitting elements LE. The organic layer OL may be referred to as a planarization layer.

In an embodiment, the organic layer OL may include one or more selected from the group consisting of a polyacrylate resin, an epoxy resin, a phenolic resin, a polyamide resin, and a polyimide resin. However, embodiments of the present invention are not limited to the above examples, and the organic layer OL may include an inorganic material.

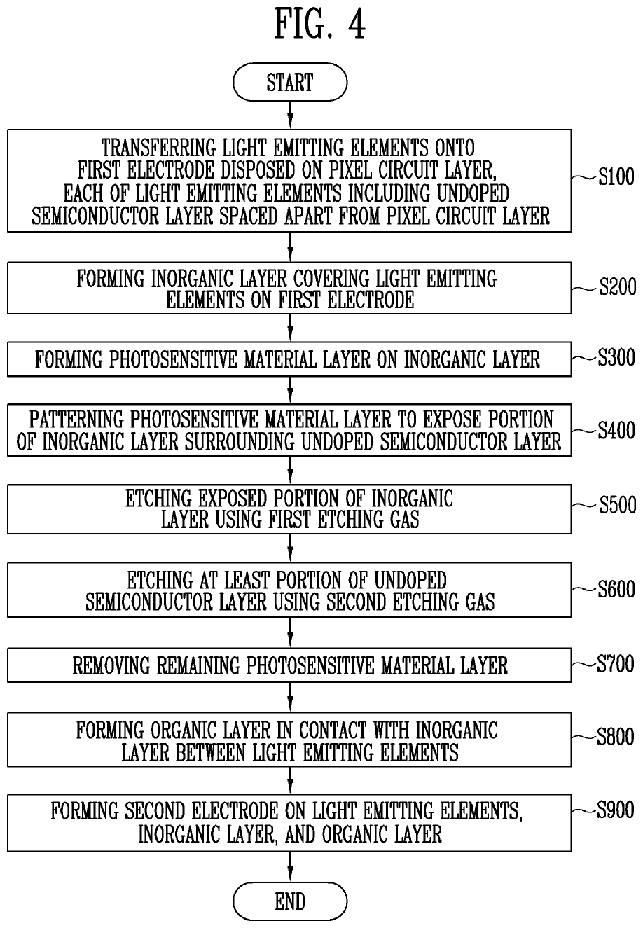

FIG. 4 is a block diagram for explaining a manufacturing method of a display device according to an embodiment; and FIGS. 5 to 14 are diagrams schematically illustrating the manufacturing method of the display device according to FIG. 4.

Referring to FIG. 4, a manufacturing method of a display device according to an embodiment may include transferring light emitting elements LE′ onto a first electrode CM disposed on a pixel circuit layer PCL, each of the light emitting elements LE′ including an undoped semiconductor layer SCL3 spaced apart from the pixel circuit layer PCL (S100); forming an inorganic layer IOL covering the light emitting elements LE′ on the first electrode CM (S200); forming a photosensitive material layer PML on the inorganic layer IOL (S300); patterning the photosensitive material layer PML to expose a portion of the inorganic layer IOL surrounding the undoped semiconductor layer SCL3 (S400); etching an exposed portion of the inorganic layer IOL using a first etching gas (S500); etching at least a portion of the undoped semiconductor layer SCL3 using a second etching gas (S600); removing the remaining photosensitive material layer PML (S700); forming an organic layer OL in contact with the inorganic layer IOL between the light emitting elements LE (S800); and forming a second electrode CE on the light emitting elements LE, the inorganic layer IOL, and the organic layer OL (S900). Herein, each manufacturing step will be described in further detail with reference to FIGS. 4 to 14.

Referring to FIGS. 4 and 5, in S100, the light emitting elements LE′ may be transferred onto the first electrode CM disposed on the pixel circuit layer PCL. In an embodiment, each of the light emitting elements LE′ may include the undoped semiconductor layer SCL3 spaced apart from the pixel circuit layer PCL. The undoped semiconductor layer SCL3 may be referred to as a third semiconductor layer SCL3.

The third semiconductor layer SCL3 may be disposed on a first semiconductor layer SCL1. The third semiconductor layer SCL3 may include an undoped semiconductor. The third semiconductor layer SCL3 may include the same material as the first semiconductor layer SCL1, but may include a material not doped with an N-type or P-type dopant. According to an embodiment, the third semiconductor layer SCL3 may include one or more selected from the group consisting of undoped InAlGaN, GaN, AlGaN, InGaN, AlN, and InN. However, embodiments of the present invention are not limited to the above examples.

In an embodiment, when the light emitting element LE′ is manufactured by forming a semiconductor layer on a substrate using an epitaxial growth method, the third semiconductor layer SCL3 (or a buffer layer) may be disposed between the semiconductor layer (for example, the first semiconductor layer SCL1) and the substrate to reduce a lattice constant difference.

In this case, since the third semiconductor layer SCL3 increases the contact resistance between the first semiconductor layer SCL1 and the second electrode CE, the light emitting efficiency of the display device may decrease. Therefore, after the light emitting element LE′ is transferred, the third semiconductor layer SCL3 is removed. In a comparative example, after the light emitting element is transferred, an organic layer covering the light emitting element is formed, a portion of the organic layer is etched to expose the third semiconductor layer, and then the third semiconductor layer is removed. However, in the process of removing the third semiconductor layer, additional consumption of the organic layer supporting the light emitting element occurs, causing a problem in that the light emitting element is lifted during a manufacturing process of the display device.

Referring to FIGS. 4 and 6, in S200, the inorganic layer IOL covering the light emitting elements LE′ may be formed on the first electrode CM. The shape or thickness of the inorganic layer IOL covering the light emitting elements LE′ is not particularly limited, and the inorganic layer IOL may be formed according to known methods.

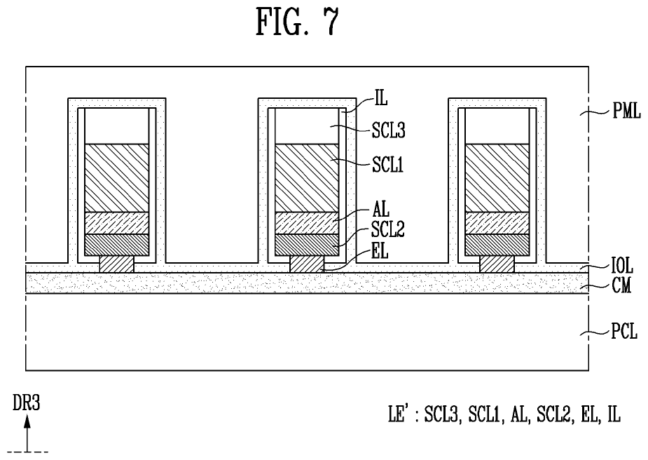

Referring to FIGS. 4 and 7, in S300, the photosensitive material layer PML may be formed on the inorganic layer IOL. The photosensitive material layer PML may include a positive type photoresist material or a negative type photoresist material. In the positive type photoresist material, a portion exposed to light may be dissolved in a developing solution. In the negative type photoresist material, a portion that is not exposed to light may be dissolved in a developing solution. Herein, for convenience of description, it is described that the photosensitive material layer PML includes a positive type photoresist material.

Referring to FIGS. 4, 8, and 9, in S400, the photosensitive material layer PML may be patterned to expose a portion of the inorganic layer IOL surrounding the undoped semiconductor layer SCL3 (or the third semiconductor layer). In an embodiment, a halftone mask HM may be used to pattern the photosensitive material layer PML. The halftone mask HM may be a mask having areas having different transmittances, and may selectively irradiate light to the photosensitive material layer PML or selectively expose the photosensitive material layer PML. For example, a semi-transmissive area A1 and a fully transmissive area A2 may be divided by the half-tone mask HM, and light generated from a light source LS may be irradiated to each area of the photosensitive material layer PML.

Thereafter, when the photosensitive material layer PML exposed through the halftone mask HM is developed, the photosensitive material layer PML overlapping the semi-transmissive area A1 may be removed by a first thickness t1, and the photosensitive material layer PML overlapping the fully transmissive area A2 may be removed by a second thickness t2 greater than the first thickness t1. In an embodiment, the photosensitive material layer PML overlapping the semi-transmissive area A1 may be removed to a thickness exposing an upper surface of the inorganic layer IOL, and the photosensitive material layer PML overlapping the fully transmissive area A2 may be removed to a thickness exposing a portion of the inorganic layer IOL surrounding the undoped semiconductor layer SCL3.

Referring to FIGS. 4 and 10, in S500, the exposed portion of the inorganic layer IOL may be etched using a first etching gas. The undoped semiconductor layer SCL3 may be exposed by etching the exposed portion of the inorganic layer IOL. For example, the exposed portion of the inorganic layer IOL may be removed by dry etching. In an embodiment, in S500, only the exposed portion of the inorganic layer IOL may be etched, and the undoped semiconductor layer SCL3 may not be etched. In an embodiment, the first etching gas may include at least tetrafluoromethane (CF₄). However, embodiments of the present invention are not limited to the above examples.

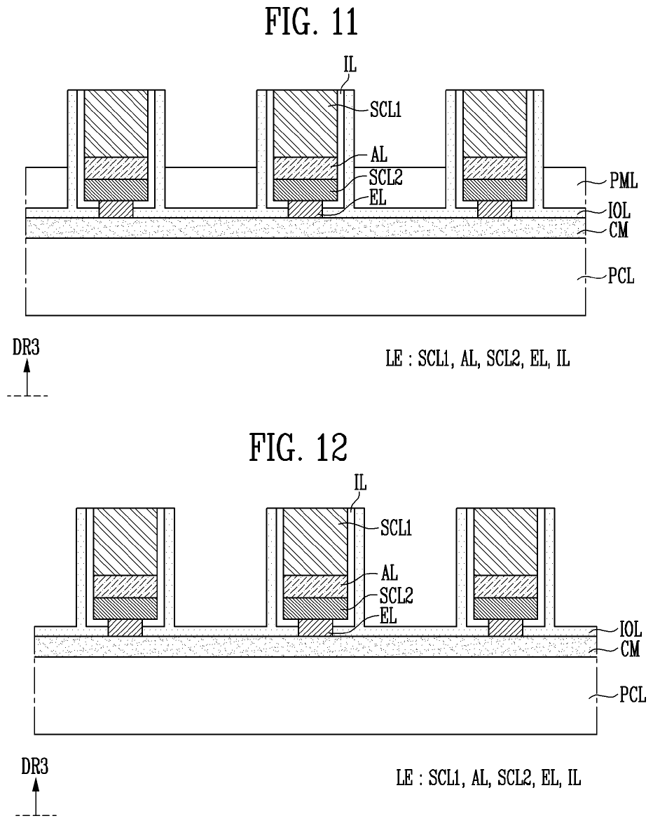

Referring to FIGS. 4 and 11, in S600, at least a portion of the undoped semiconductor layer SCL3 may be etched using a second etching gas. For example, the undoped semiconductor layer SCL3 may be removed by dry etching. In an embodiment, in S600, at least a portion of the photosensitive material layer PML as well as the undoped semiconductor layer SCL3 may be etched. That is, when the second etching gas is used, exposed portions of the undoped semiconductor layer SCL3 and the photosensitive material layer PML may be etched together. In an embodiment, the second etching gas may include at least boron trichloride (BCl₃). However, embodiments of the present invention are not limited to the above examples. As such, according to embodiments of the present invention, the undoped semiconductor layer SCL3 may be stably removed without consuming the organic layer OL.

Referring to FIGS. 4 and 12, in S700, the remaining photosensitive material layer PML may be removed. For example, S700 may correspond to a process of stripping and removing the remaining photosensitive material layer PML. That is, S700 may be performed when the photosensitive material layer PML is not completely removed during S600, and may be omitted when the photosensitive material layer PML is completely removed during S600.

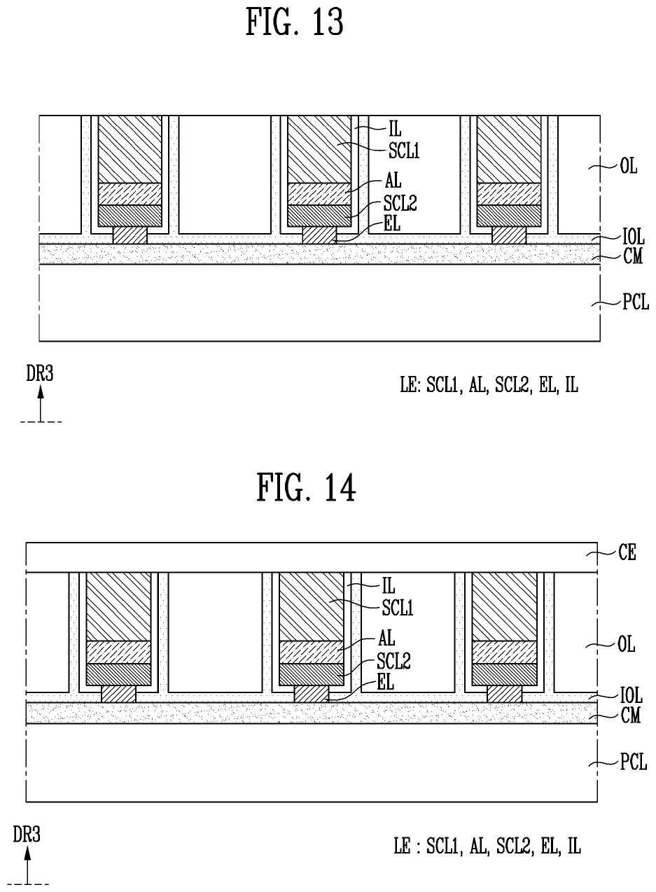

Referring to FIGS. 4 and 13, in S800, the organic layer OL in contact with the inorganic layer IOL may be formed between the light emitting elements LE. That is, according to embodiments of the present invention, the organic layer OL may be stably formed without consuming the organic layer OL. Accordingly, lifting of the light emitting elements LE may be prevented or substantially prevented during a manufacturing process.

Referring to FIGS. 4 and 14, in S900, the second electrode CE contacting the light emitting elements LE, the inorganic layer IOL, and the organic layer OL may be formed. That is, as the undoped semiconductor layer SCL3 is removed, the first semiconductor layer SCL1 of the light emitting elements LE may be in contact with the second electrode CE, and contact resistance between the first semiconductor layer SCL1 and the second electrode CE may be reduced, thereby increasing the light emitting efficiency of the display device.

According to an aspect of embodiments of the present invention, the light emitting efficiency of the display device can be increased by improving the contact resistance between the N-type semiconductor layer and the cathode electrode of the light emitting element.

According to another aspect of embodiments of the present invention, the undoped semiconductor layer of the light emitting element can be effectively removed without the risk of lifting the light emitting element during the manufacturing process.

However, aspects and effects of the present invention are not limited to the above-described aspects and effects, and may be variously extended without departing from the spirit and scope of the present invention.

Although the present invention has been specifically described according to the above-described embodiments, it is to be understood that the above-described embodiments are intended to illustrate the present invention and not to limit the scope of the present invention. Those of ordinary skill in the art to which the present invention pertains will understand that various modifications are possible within the scope of the technical spirit of the present invention.

Therefore, the technical protection scope of the present invention is not limited to the description of the above-described embodiments, but should be determined by the claims. In addition, all changes or modifications derived from the meaning and scope of the claims and their equivalents should be construed as being included in the scope of the present invention.

What is claimed is:

1. A manufacturing method of a display device, the manufacturing method comprising:
transferring light emitting elements onto a first electrode arranged on a pixel circuit layer, each of the light emitting elements comprising an undoped semiconductor layer spaced apart from the pixel circuit layer;
patterning an inorganic layer covering the light emitting elements on the first electrode;
forming a photosensitive material layer on the inorganic layer; and
patterning the photosensitive material layer to expose a portion of the inorganic layer covering the undoped semiconductor layer.

2. The manufacturing method of claim 1, wherein the inorganic layer comprises at least one of silicon oxide or silicon nitride.

3. The manufacturing method of claim 1, wherein the patterning the photosensitive material layer comprises:
exposing and developing the photosensitive material layer using a halftone mask.

4. The manufacturing method of claim 1, further comprising:
etching an exposed portion of the inorganic layer using a first etching gas.

5. The manufacturing method of claim 4, wherein the first etching gas comprises at least tetrafluoromethane.

6. The manufacturing method of claim 4, further comprising:
etching at least a portion of the undoped semiconductor layer using a second etching gas.

7. The manufacturing method of claim 6, wherein the second etching gas comprises at least boron trichloride.

8. The manufacturing method of claim 6, wherein in the etching the at least the portion of the undoped semiconductor layer, at least a portion of the patterned photosensitive material layer is etched.

9. The manufacturing method of claim 8, further comprising:
removing the patterned photosensitive material layer remaining unetched.

10. The manufacturing method of claim 9, further comprising:
forming an organic layer in contact with the inorganic layer between the light emitting elements.

11. The manufacturing method of claim 10, further comprising:
forming a second electrode on the light emitting elements, the inorganic layer, and the organic layer.

12. A display device comprising:
a pixel circuit layer comprising a base layer and a pixel circuit;
a first electrode on the pixel circuit layer;
light emitting elements on the first electrode and each comprising a first semiconductor layer including a first type semiconductor;
an inorganic layer on the first electrode and covering the light emitting elements; and
a second electrode on the light emitting elements,
wherein the first semiconductor layer and the inorganic layer contact the second electrode.

13. The display device of claim 12, wherein each of the light emitting elements further comprises:
a second semiconductor layer including a second type semiconductor different from the first type semiconductor;
an active layer between the first semiconductor layer and the second semiconductor layer; and
an electrode layer on the second semiconductor layer,
wherein the second semiconductor layer, the active layer, and the electrode layer are between the first electrode and the first semiconductor layer.

14. The display device of claim 13, wherein each of the light emitting elements further comprises an insulating layer surrounding at least a portion of each of the first semiconductor layer, the second semiconductor layer, the active layer, and the electrode layer.

15. The display device of claim 12, wherein the inorganic layer comprises at least one of silicon oxide or silicon nitride.

16. The display device of claim 12, further comprising:
an organic layer between the light emitting elements and contacting the inorganic layer and the second electrode.
